(19) United States
(12) Patent Application Publication
(10) Pub. No.: US 2008/0199811 A1
(43) Pub. Date: Aug. 21, 2008

(54) PHOTOSENSITIVE COMPOSITION AND TWO-PHOTON ABSORPTION PHOTORECORDING MEDIUM

(75) Inventors: Yoshio INAGAKI, Ashigarakami-gun (JP); Koichi Kawamura, Ashigarakami-gun (JP)

Correspondence Address: BIRCH STEWART KOLASCH & BIRCH, PO BOX 747, FALLS CHURCH, VA, 22040-0747, US

(73) Assignee: FUJIFILM Corporation, Tokyo (JP)

(21) Appl. No.: 12/034,413

(22) Filed: Feb. 20, 2008

(30) Foreign Application Priority Data
Feb. 20, 2007 (JP) 2007-040067

(51) Int. Cl. G03F 7/004

(52) U.S. Cl. 430/286.1

(57) ABSTRACT

A photosensitive composition containing a binder polymer, a polymerizable compound, and a compound of formula (I):

D-L-A formula (I)

wherein D represents a light-absorptive portion composed of a group to give a two-photon absorption compound which is 100 GM or larger of two-photon absorption cross-section in a wavelength longer than 400 nm; A represents an active portion capable of interacting with the light-absorptive portion D that is excited by light, to generate free radicals; and L represents a linking group which links the light-absorptive portion D with the active portion A.

### FIELD OF THE INVENTION

The present invention relates to a photosensitive composition utilizable for image formation or detection of three-dimensional light, or to a two-photon absorption photorecording medium utilizing the same; and particularly, the present invention relates to a two-photon absorption photosensitive composition containing a compound having a large two-photon absorption cross-section capable of being excited only by a strong intensity of light, and to a two-photon absorption photorecording medium utilizing the same.

### BACKGROUND OF THE INVENTION

Normally, a molecule absorbs a photon when its energy is equal to the energy gap of the molecule, but does not when the energy of a photon does not fulfill this condition. In case the intensity of light is extremely high (higher in photon density), however, even such photons having less energy to the energy gap of the molecule can be absorbed by a molecule to generate an excited state of the molecule. By taking advantage of this property, a photoreaction can be initiated only in a very small region close to the focal point of the tightly focused laser light so that it can be utilized to make the excited state with three-dimensional special resolution. The two-photon absorption cross-sections are usually extremely small because of their third-order nonlinear optical nature, so that molecules possessing large two-photon absorption cross-sections are strongly demanded for a practical application. Two-photon absorption cross-sections of molecules, which represent easiness for causing two-photon absorption, are very small and usually as large as about 1 GM (precisely, 1 GM=1×10⁻⁵⁰ cm⁴s molecule⁻¹photon⁻¹). In recent years, molecules showing relatively large two-photon absorption cross-sections of approximately several hundred to several thousand GMs are synthesized. Examples of the molecules having relatively large two-photon absorption cross-sections arc described or quoted, for example, in Reinhardt et al., “Chemistry of Materials” 1998, Vol. 10, p. 1863; M. Albota et al., “Science”, 1998, Vol. 281 p. 1653; M. Rumi et al., “Journal of the American Chemical Society”, 2000, 122, p. 9500; J. D. Bhwalkar et al., “Optics Communications”, 1996, Vol. 124, p. 33; G. S. He et al., “Applied Physics Letters”, 1995 Vol. 67, p. 2433; P. N. Prasad et al., “Nonlinear Optics”, 1999, Vol. 21, p. 39; G. S. He et al., “Journal of Applied Physics”, 1997, Vol. 81, p. 2529; S.-J. Chung et al., “Journal of Physical Chemistry B”, 1999, Vol. 103, p. 10741; G. S. He et al., “Optics Letters”, 1995, Vol. 20, p. 435; J. W. Perry et al., “Nonlinear Optics”, 1999, Vol. 21, p. 225; and Yoshio Inagaki and Masaatsu Akiba “The Review of LASER Engineering”, 2003 vol. 31, pp. 392-396.

Not only two-photon absorption properties but also other functionalities of molecules are needed to combine for a practical application to use excited energy acquired through two-photon absorption process.

It is known, for example, that excited energy acquired through light absorption is transferred to a radical-generating agent to form free radicals which can initiate polymerization reactions of vinyl monomers. Alternatively, it is assumed that it is possible to cause a coloring reaction or discoloring reaction, by transferring energy of an exited state, which is generated by light absorption, to coloring compounds or discoloring compounds. From the past, therefore, photopolymerizations are carried out with a mixture of a polymerization initiator and a two-photon absorption compound (for example, a sensitizer dye having absorption in visible wavelength region). A mechanism for generating active species between the sensitizer dye and the polymerization initiator resides in that a reaction is promoted by an electron-transferring reaction between the excited state of the sensitizer dye generated by photon absorption of visible light and the initiator whereby active species, such as free radicals or cations, are generated from the initiator, and the active species causes generation and proceeding of the polymerization.

If the two-photon absorption is to be utilized, however, the two-photon excitation efficiency is low in its nature, and moreover, there is a limitation in the amount of free radical generating agents, coloring compounds, and two-photon absorption compounds to add. Thus, probability of existing the two-photon absorbing compound and the free radical generator compound, which are in exited states, in a mutually adjacent position is extremely low so that efficient energy transfer does not necessarily take place. In general, electron transfer reactions in a solid matrix like a two-photon photosensitive composition for recording use are different from that in a solution, and the sensitizer dye and the polymerization initiator cannot be freely diffused so that the efficiency of the electron-transferring greatly depends on the distance between the sensitizer dye and the polymerization initiator. The efficiency of excited state electron transfer depends on the distance between those dyes and initiators, but the efficiency decreases exponentially in terms of the distance between the sensitizer dyes and initiators. The distance between the sensitizer dyes and the polymerization initiators in the solid matrix depend on the concentration of the polymerization initiator added so that the distance naturally becomes longer when the concentration is low, thereby extremely reducing the efficiency of the transfer of electrons. In other words, a high sensitivity could not be expected in a desirable addition range of a relatively low concentration as the two-photon photosensitive composition for recording use.

### SUMMARY OF THE INVENTION

The present inventors, having extensively studying the above, have found that radicals are efficiently generated through excited state energy transfer from higher excited states generated by two-photon absorption, by using a compound represented by formula (I), i.e. a compound having the structure in which a light-absorptive portion D capable of two-photon absorption and an active portion A capable of generating free radicals are linked by a linking portion L. The present invention has been accomplished by the above finding.

D-L-A Formula (I)

In formula (I), D represents a light-absorptive portion composed of a group to give a two-photon absorption compound which is 100 GM or more in two-photon absorption cross-section in a wavelength longer than 400 nm; A represents an active portion capable of interacting with the light-absorptive portion D that is excited by light, to generate free radicals; and L represents a linking group which links the light-absorptive portion D with the active portion A.

Other and further features and advantages of the invention will appear more fully from the following description.

### DETAILED DESCRIPTION OF THE INVENTION

According to the present invention, there is provided the following means:
[1] A photosensitive composition, containing a binder polymer, a polymerizable compound, and a compound represented by formula (I):

D-L-A Formula (I)

wherein D represents a light-absorptive portion composed of a group to give a two-photon absorption compound which has at least 100 GM in two-photon absorption cross-section in a wavelength longer than 400 nm; A represents an active portion capable of interacting with the light-absorptive portion D that is excited by light, to generate free radicals; and L represents a linking group which links the light-absorptive portion D with the active portion A.
[2] The photosensitive composition according to [1], wherein the compound represented by formula (I) is contained in an amount of 0.1 to 3.0% by mass.
[3] The photosensitive composition according to [1 or [2], wherein the linking group L in formula (I) represents a linking group containing at least one linkage selected from the group consisting of a methylene bond, an ester bond, an amide bond, a sulfonamide bond, an ether bond, and a thioether bond; and the light-absorptive portion D and the active portion A are linked by a non-conjugated bond.
[4] The photosensitive composition according to any one of [1] to [3], wherein the light-absorptive portion D is a group derived from a compound represented by formula (II) or (III):

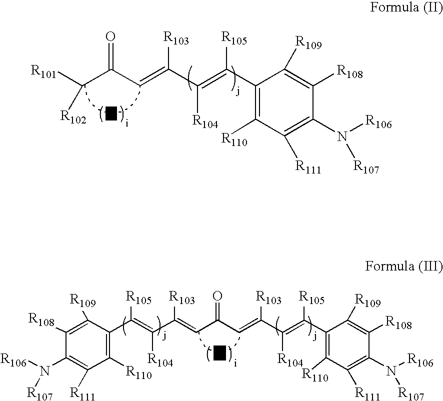

wherein Y represents a methine or methylene group, which may be substituted by a halogen atom, an alkyl group having 1 to 18 carbon atoms, an alkoxy group having 1 to 18 carbon atoms, or an aryl group having 6 to 18 carbon atoms; i represents an integer of 1 to 4; R₁₀₁ and R₁₀₂ each independently represent a hydrogen atom, an alkyl group having 1 to 18 carbon atoms, or an aryl group having 6 to 18 carbon atoms; R₁₀₃, R₁₀₄ and R₁₀₅ each independently represent a hydrogen atom, a halogen atom, an alkyl group having 1 to 18 carbon atoms, or an aryl group having 6 to 18 carbon atoms; j represents an integer of 0 to 3; R₁₀₆ and R₁₀₇ each independently represent an alkyl group having 1 to 18 carbon atoms, or an aryl group having 6 to 18 carbon atoms; R₁₀₈, R₁₀₉, R₁₁₀ and R₁₁₁ each independently represent a hydrogen atom, a halogen atom, a cyano group, an alkyl group having 1 to 18 carbon atoms, an alkoxy group having 1 to 18 carbon atoms, an acyl group having 1 to 18 carbon atoms, an acylamino group having 1 to 18 carbon atom, a carbamoyl group having 1 to 18 carbon atom, a sulfonamido group having 1 to 18 carbon atoms, a sulfamoyl group having 1 to 18 carbon atoms, an amino group, an alkylamino group having 1 to 18 carbon atoms, an arylamino group having 6 to 18 carbon atoms, or a hydroxyl group, in which any two of these groups may bond together, to form a ring; and any one of R₁₀₁ to R₁₁₁ has at least one functional group necessary for reacting with a compound containing the active portion A, to form the linking group L.
[5] The photosensitive composition according to any one of [1] to [4], wherein the active portion A is a group derived from a compound represented by formula (IV):

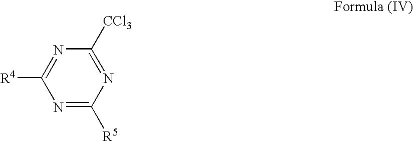

wherein R⁴ and R⁵ each independently represent a hydrogen atom, an alkyl group, a substituted alkyl group, an aryl group, a substituted aryl group, an alkenyl group, or a substituted alkenyl group, in which one of R⁴ and R⁵ has at least one functional group necessary for reacting with a compound containing the light-absorptive potion D, to form the linking group L.
[6] A two-photon absorption photorecording medium, having a photosensitive layer containing the photosensitive composition according to any one of [1] to [5].

Hereinafter, the present invention is explained in detail.

### [Photosensitive Composition]

The photosensitive composition (e.g. a two-photon absorption composition) of the present invention contains, as indispensable components thereof, (A) a binder polymer, (B) a polymerizable compound, and (C) a compound represented by formula (I) (i.e. a photopolymerization initiator):

D-L-A Formula (I)

wherein D represents a light-absorptive portion composed of a group to give a two-photon absorption compound which has 100 GM or larger two-photon absorption cross-section in the wavelength longer than 400 nm; A represents an active portion capable of interacting with the light-absorptive portion D that is excited by light, to generate free radicals; and L represents a linking group which links the light-absorptive portion D with the active portion A.

In the case where a polymerization initiator is added at a low concentration in a conventional system in which a two-photon excitation compound and the polymerization initiator are separately added in the system, probability of existing the two-photon absorption compound and the initiator in mutually adjacent position is extremely low even if homogeneous dispersion is carried out favorably enough so that efficient energy transfer hardly takes place. Contrary to the above, the compound represented by formula (I) to be used in the photosensitive composition of the present invention has such a structure that the sensitizer dye portion (the light-absorptive portion D) and the radical polymerization initiator portion (the active portion A) are linked with the linking group L, so that it is possible to transfer the energy efficiently from the high-excited state by two-photon absorption, thereby to generate radicals, due to that structure. To say it in another way, the two-photon excitation portion (the light-absorptive potion D) due to exposure to light and the portion where the activation takes place by transferring the energy to generate free radicals (the active potion A) exist in a very close position to ensure that transferring of electron between those portions is carried out quickly and efficiently so that the active species (free radicals) are generated in an extremely large amount as compared with the conventional system in which a two-photon excitation compound and a polymerization initiator are separately added. It is presumed, therefore, that a sufficient sensitivity is acquired in the photosensitive composition of the present invention even in case the content of the polymerization initiator is small.

Moreover, the two-photon absorption photorecording medium obtained by the use of the photosensitive composition can be satisfied in a small amount in the content of the photopolymerization initiator as compared with the conventional photorecording medium. As a result, a residual unreacted initiator and/or decomposed matter thereof becomes small so that the present invention has an advantageous feature that any bad influence on physical properties or optical characteristics of the recording film due to those undesirable remaining matters can be inhibited to the minimum.

Next, the indispensable components of the photosensitive composition of the present invention will be explained one by one. At the outset, an explanation is given for (C) the compound represented by formula (I) (photopolymerization initiator) which is an important component for the present invention.

### (C) Compound Represented by Formula (1) (Photopolymerization Initiator):

The photopolymerization initiator that can be used in the present invention is a compound represented by formula (I), i.e. a compound having a structure provided in its molecule with a light-absorptive portion having a function of a sensitizer dye and an active portion having a function of generating an active species, these portions being linked with a given linking group. The photosensitive composition of the present invention contains the compound as a photo-radical polymerization initiator or a photo-cation polymerization initiator.

D-L-A Formula (I)

In formula (I), D represents a light-absorptive portion composed of a group to give a two-photon absorption compound whose two-photon absorption cross-section in the wavelength region longer than 400 nm is 100 GM or larger; A represents an active portion capable of interacting with the light-absorptive portion D that is excited by a light, to generate free radicals; and L represents a linking group which links the light-absorptive portion D with the active portion A.

The compound represented by formula (I) according to the present invention is described in detail. In the below-mentioned Exemplified compound S1, the distance between the light-absorptive portion (the sensitizer dye) and the active portion (the initiator) is approximately 12 Å, estimated from the MM 2 molecule calculation. On the other hand, in the case where this compound is contained in the photosensitive composition at a concentration of 3 mmol/dm³ (in case of the Exemplified compound S1, it corresponds to a concentration of 0.3% by mass in the composition), for example, the distance between the sensitizer dye and the initiator is estimated as 51 Å if both of those two are separately contained at such concentration. As a result, the difference in distance in those two cases is thus approximately 40 Å. According to the literatures, it is reported that whenever every several Å distance is apart, there is a fall of electron transfer velocity of several hundred to several thousand times reduction. In view of that, in such an amount of content, the above difference in distance reveals that a satisfactory sensitivity cannot be achieved unless the specific polymerization initiator according to the present invention is used.

The light-absorptive portion D in formula (I) is explained below. D represents a light-absorptive portion composed of a group to give a two-photon absorption compound which is at least 100 GM in two-photon absorption cross-section in the wavelength longer than 400 nm.

An explanation is given for behavior principle of the composition capable of exhibiting function responsible only to a high-intensity light (light of high photon density) that can be applied to the two-photon absorption composition of the present invention. When a substance is irradiated with light, an energy corresponding to 1 photon is usually absorbed. Although with a light of a wavelength that does not cause such a one-photon absorption, there may be the case where two-photons of which the sum of photon energies corresponds to the excitation energy are concurrently absorbed, when the intensity of the light is extremely high. Generally, two-photon absorption cross-section showing easiness for causing two-photon absorption is very small, and it is about 1 GM (precisely, 1 GM=1×10⁻⁵⁰ cm⁴s molecule⁻¹photon⁻¹). In recent years, substances showing a relatively large two-photon absorption cross-section of approximately several hundred to several thousand GMs are found. In case where such a substance is employed, the use of a light-source very high in intensity, such as a high output laser, enables absorption of two-photon's energies, even if the light is within a wavelength region having no light absorption band. For example, when a compound showing the maximum absorption wavelength of 1-photon at 400 nm but no light absorption band at 800 nm, is irradiated with a high output laser of wavelength 800 nm, it enables to cause an excited state almost equivalent to the excited state occurred by irradiation with a light at 400 nm.

If the compound is excited with light at 400 nm, to emit, for example, fluorescence at 430 nm, the compound will also emit fluorescence at 430 nm even in case of absorbing light at 800 nm. Further, if a compound absorbing light at 430 nm to emit fluorescence at 460 nm is coexistent, it will emit fluorescence at 460 nm by irradiation with a high output laser at 800 nm. There is such a characteristic that if irradiation is carried out with laser beam by stopping down the lens, the resultant light is to be emitted from not the whole light path, but fluorescence is to be emitted from only the vicinity of the focus where photon density is high, thus being capable for imparting the three-dimensional selectivity in location or position. The use of a polymerization initiator and a polymerizable monomer or a polymerizable oligomer in mixture in place of the compound capable of emitting fluorescence, makes it possible to initiate polymerization only in the vicinity of the focus so that a solid polymer of any appropriate shape can be formed. Furthermore, since the intensity of the stopped down laser beam becomes lower as the beam is more distant from the center thereof, a portion having the light intensity sufficient to cause two-photon excitation is smaller than the diameter of the beam and is about 1/√2 times, i.e. about 0.7 times, the diameter. Consequently, it is an advantageous feature that a very fine area can only be excited which is finer than the minimum value of the beam diameter as determined by the wavelength of light. The composition of the present invention thus exhibits its function.

Preferably in the present invention and sufficiently for a target two-photon absorption to take place more efficiently rather than two-photon absorption of the coexistent binder or support, the two-photon absorption cross-section is preferably 100 GM or larger, more preferably 1,000 GM or larger, and especially preferably 100,000 GM to 1,000,000 GM, conveniently expressed in terms of GM (Goeppert-Mayer's unit, i.e., 1×10⁻⁵⁰ cm⁴s molecule⁻¹photon⁻¹). The measurement of the two-photon absorption cross-section is performed according to the fluorescence method and the Z-scan method described in the following literatures:
[Fluorescence method]: C. Xu and W. W. Webb, Journal of the Optical Society of America, B, 13, 481 (1996)
[Z-scan methods]: K. Kamada, K. Matsumoto, A. Yoshino, and K. Ohta, Journal of the Optical Society of America, B, 20, 529 (2003); P. Audebert, K. Kamada, K. Matsunaga, and K. Ohta, Chemical Physics Letters, 367, 62 (2003)

The two-photon absorption wavelength range is preferably a wavelength longer than 400 nm, and it is more preferably 500 to 1,100 nm.

Examples of the compound containing the light-absorptive portion D which is composed of a group to give a two-photon absorption compound whose two-photon absorption cross-section in wavelength longer than 400 nm is 100 GM or more, include any light-absorbing agent that has been conventionally used in combination with an active agent, for example, those described in the literatures listed in the paragraph of the above “BACKGROUND OF THE INVENTION”. Illustrative of the compound include, for example, chalcone-series compounds, dibenzylacetone-series compounds, merocyanine dyes, thiopyrylium dyes, pyrylium dyes, dialkylaminostilbene compounds, acridinium dyes, xanthene dyes, and thiazine dyes, as well as cyanine dyes, squalium dyes, xanthene-series dyes, triphenylmethane-series dyes, and thioxanthone, etc.

Further, other examples include polynuclear aromatic compounds, such as anthracene, phenanthrene, and pyrene etc.; polynuclear heteroaromatic compounds, such as acridine, carbazole, and phenothiazine, etc; and derivatives thereof.

Further, the light-absorption portion D is preferably a group derived from a compound represented by formula (II) or (III):

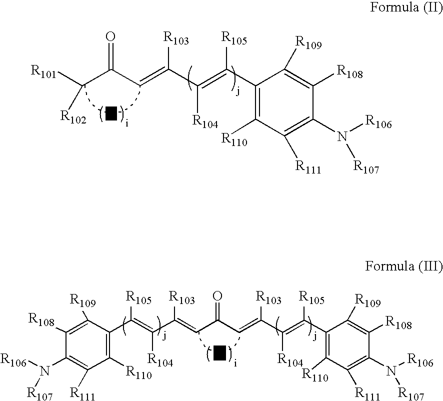

In formulae (II) and (III), Y represents a methine or methylene group, which may be substituted by a halogen atom, an alkyl group having 1 to 18 carbon atoms, an alkoxy group having 1 to 18 carbon atoms, or an aryl group having 6 to 18 carbon atoms; i represents an integer of 1 to 4; R₁₀₁ and R₁₀₂ each independently represent a hydrogen atom, an alkyl group having 1 to 18 carbon atoms, or an aryl group having 6 to 18 carbon atoms; R₁₀₃, R₁₀₄ and R₁₀₅ each independently represent a hydrogen atom, a halogen atom, an alkyl group having 1 to 18 carbon atoms, or an aryl group having 6 to 18 carbon atoms; j represents an integer of 0 to 3; R₁₀₆ and R₁₀₇ each independently represent an alkyl group having 1 to 18 carbon atoms, or an aryl group having 6 to 18 carbon atoms; R₁₀₈, R₁₀₉, R₁₁₀ and R₁₁₁ each independently represent a hydrogen atom, a halogen atom, a cyano group, an alkyl group having 1 to 18 carbon atoms, an alkoxy group having 1 to 18 carbon atoms, an acyl group having 1 to 18 carbon atoms, an acylamino group having 1 to 18 carbon atom, a carbamoyl group having 1 to 18 carbon atom, a sulfonamido group having 1 to 18 carbon atoms, a sulfamoyl group having 1 to 18 carbon atoms, an amino group, an alkylamino group having 1 to 18 carbon atoms, an arylamino group having 6 to 18 carbon atoms, or a hydroxyl group, in which any of these groups may further have a substituent (e.g. a carboxyl group, and the like), or any two of those groups may bond together, to form a ring; and any one of R₁₀₁ to R₁₁₁ has at least one functional group necessary for reacting with a compound containing the active portion A, thereby to form the linking group L.

It is preferable that Y is a unsubstituted methylene group (i.e. —CH₂—), —NH—, or —NR— (in which R represents an alkyl group having 1 to 18 carbon atoms, an aryl group having 6 to 18 carbon atoms, an acyl group having 2 to 18 carbon atoms, an alkylsulfonyl group having 1 to 18 carbon atoms, or an arylsulfonyl group having 6 to 18 carbon atoms).

It is preferable that R₁₀₁ and R₁₀₂ each independently are a hydrogen atom, or an alkyl group having 1 to 6 carbon atoms.

It is preferable that R₁₀₃, R₁₀₄ and R₁₀₅ each independently are a hydrogen atom, or an alkyl group having 1 to 3 carbon atoms. Two of R₁₀₃, R₁₀₄ and R₁₀₅ may be bonded together to form a ring. Especially preferable is the hydrogen atom.

It is preferable that R₁₀₆ and R₁₀₇ each independently are an alkyl group having 1 to 6 carbon atoms, which may have a substituent or substituents. It is preferable that the substituent(s) is a hydroxyl group, an amino group, an acylamino group, a sulfonylamino group, an acyl group, an alkoxycarbonyl group, an aryloxycarbonyl group, a carboxyl group, or a sulfonic acid group. Especially preferable as R₁₀₆ or R₁₀₇ is an unsubstituted alkyl group having 1 to 4 carbon atoms, or an alkyl group substituted by a hydroxy group having 1 to 4 carbon atoms.

It is preferable that R₁₀₈, R₁₀₉, R₁₁₀ and R₁₁₁ each independently are a hydrogen atom, or an alkyl group having 1 to 6 carbon atoms. Any two of these groups may be bonded together, or any one of those groups may be bonded with R₁₀₆ or R₁₀₇, to form a ring. Especially preferable is a hydrogen atom; or an alkyl group bonded with at least one of R₁₀₆ and R₁₀₇, to form a 5- or 6-member ring.

Specific examples of the two-photon absorption compounds represented by formula (II) or (III) are shown below, but the present invention is not limited to these compounds.

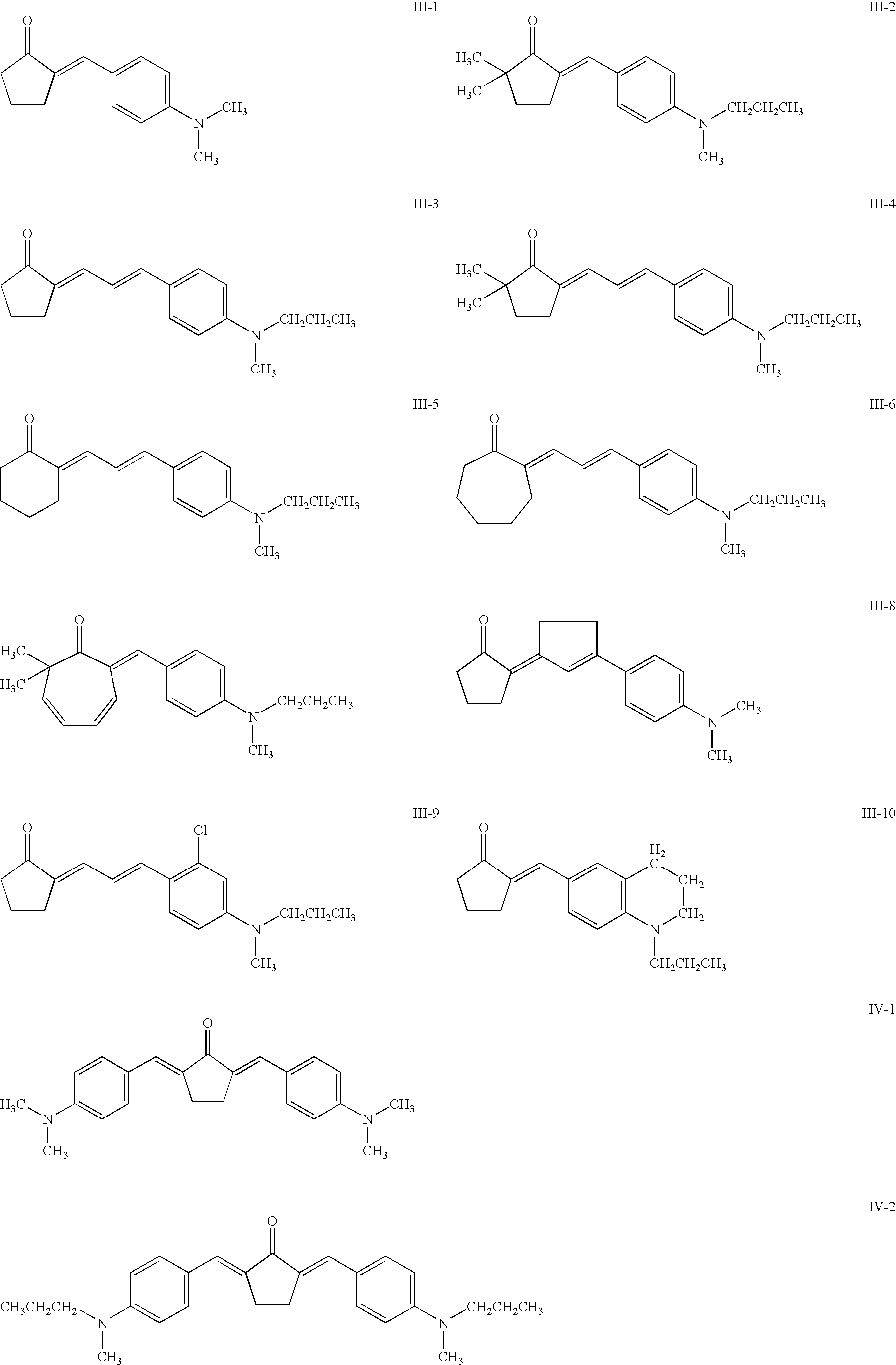

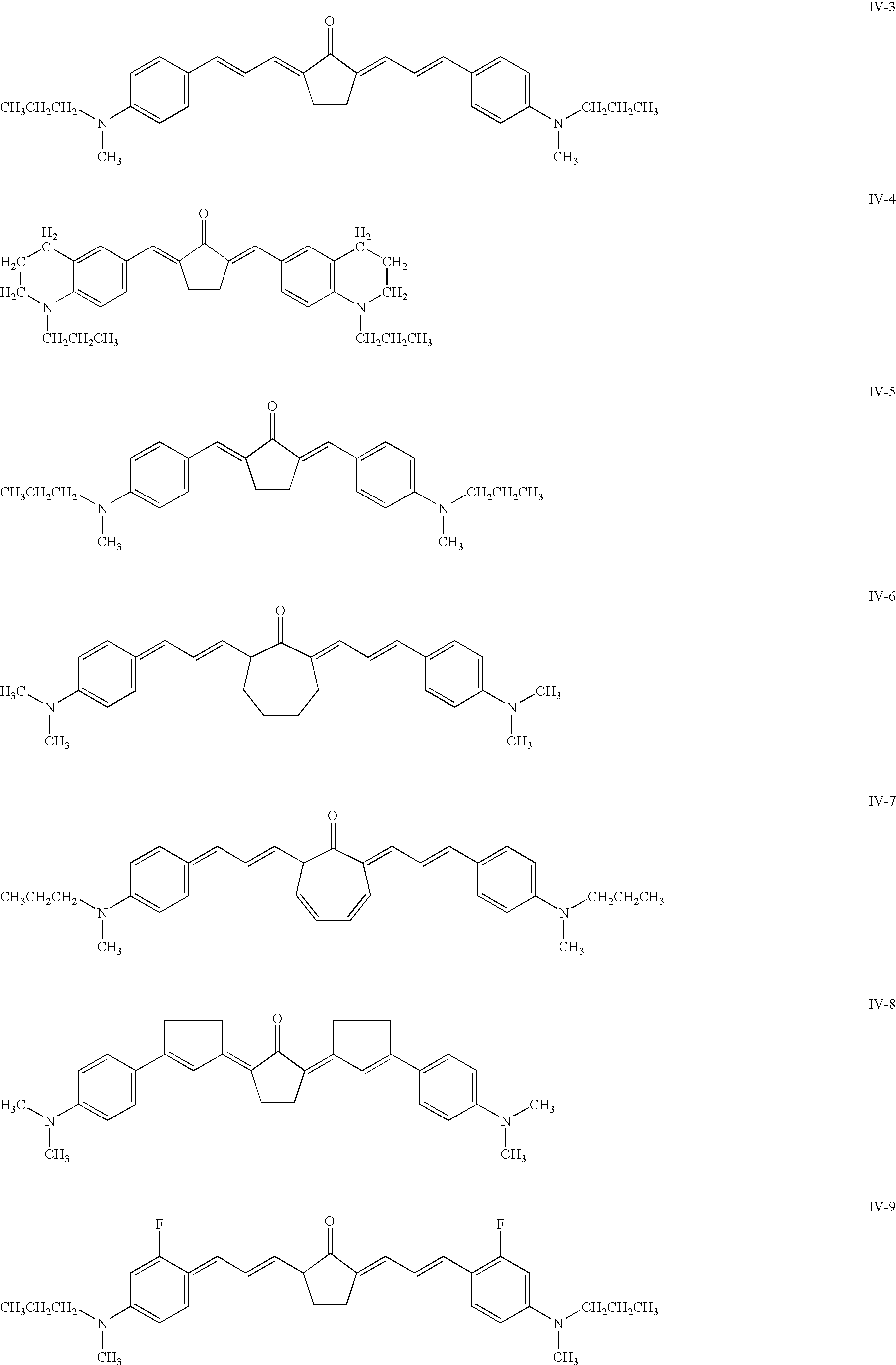

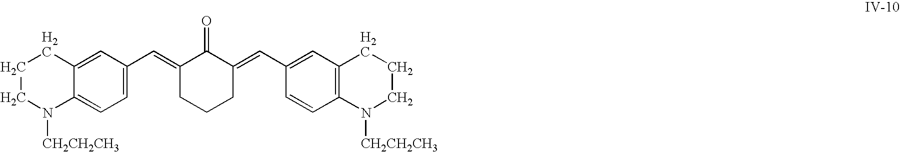

Next, the active portion A in the compound represented by formula (I) is explained in detail below. The portion A represents an active portion which interacts with the light-absorptive portion D that is excited by light, thereby to generate free radicals. The active portion A means a group to give a compound having the active portion A, from which the linking portion to the linking group L is eliminated.

Specific examples of the compound having the active portion A include, as representative examples, bis-imidazole compounds; onium compounds, such as diphenyliodonium and triphenylsulfonium salts; trichloromethyl-substituted S-triazine compounds, and N-phenylglycin; as well as amines, such as triethanolamine and hydrazine; phosphorus compounds, such as triphenylphosphine and tri-n-butylphosphine; sulfinic acids, such as sodium p-toluenesulfinate; sulfonates, such as methyl p-toluenesulfonate; heterocyclic compounds, such as oxazole and imidazole; enolate compounds, such as dimedone; tin compounds, such as tributylbenzyl tin; allylthioureas or oxime esters; borane compounds, such as triphenyl n-butyl borate; and pyridinium salts, such as 1-methoxy-4-carbomethoxypyridinium tetrafluoroborate, as described in “Research Disclosure”, Vol. 200 (December 1980) Item 20036.

Among those compounds, an S-triazine compound containing a trichloromethyl group as the active portion A is preferable, and a compound represented by formula (IV) is especially preferable.

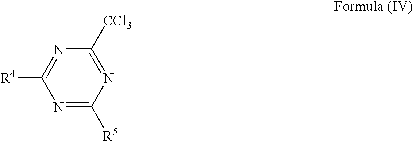

In formula (IV), R⁴ and R⁵ each independently represent a hydrogen atom, an alkyl group, a substituted alkyl group, an aryl group, a substituted aryl group, an alkenyl group, or a substituted alkenyl group, in which one of R⁴ and R⁵ has at least one functional group necessary for reacting with the compound containing the light-absorptive potion D, thereby to form the linking group L.

As the alkyl group shown by R⁴ and R⁵, a straight chain, branched or cyclic alkyl group having 1 to 18 carbon atoms is preferable. Illustrative are, for example, methyl, ethyl, propyl, 2-ethylhexyl, and cyclohexyl. As the aryl group, an aryl group having 6 to 10 carbon atoms is preferable, for example, phenyl or 1-naphthyl. As the alkenyl group, an alkenyl group having 2 to 18 carbon atoms is preferable, for example, vinyl or cyclohexenyl.

Examples of the substituent in the substituted alkyl, substituted aryl, or substituted alkenyl group include a halogen atom, an alkoxy group having 1 to 18 carbon atoms, an aryloxy group having 6 to 18 carbon atoms, an acyl group having 1 to 18 carbon atoms, an acylamino group having 1 to 18 carbon atoms, a sulfonamido group having 1 to 18 carbon atoms, an acyloxy group having 1 to 18 carbon atoms, an alkoxycarbonyl group having 2 to 18 carbon atoms, and a sulfonyl group having 1 to 18 carbon atoms.

Specific examples of the substituted alkyl group shown by R⁴ and R⁵ include trichloromethyl and trifluoromethyl. Specific examples of the substituted aryl group include 4-styrylphenyl and 4-(substituted)styrylphenyl. Specific examples of the substituted alkenyl group include styryl and substituted styryl. Specific examples of the aryl group include groups to give any of polynuclear aromatic compounds, such as naphthyl, and groups to give heteroaromatic compounds, such as thiofuran,

Furthermore, as the compound having the active portion A, sulfonium compounds or iodonium compounds represented by formula (V) or (VI) are also preferable, in addition to the compounds represented by formula (IV).

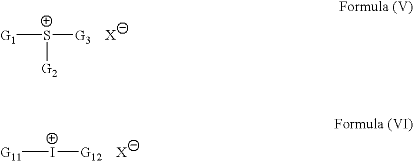

In formula (V) or (VI), G₁ to G₃, G₁₁ and G₁₂ each independently represent an alkyl group, an aryl group, or an aralkyl group. X represents an anion for neutralization of electric charge. Any of the G₁ to G₃ and one of the G₁₁ and G₁₂ has, respectively, at least one functional group necessary for reacting with a compound having the light-absorptive portion D so as to form the linking group L.

As the alkyl group represented by the G₁ to G₃, G₁₁ and G₁₂ in formula (V) or (VI), a straight chain, branched or cyclic alkyl group having 1 to 18 carbon atoms are preferable, for example, methyl, ethyl, 2-methylbutyl, or cyclohexyl. As the aryl group, preferred is an aryl group having 6 to 18 carbon atoms, for example, phenyl or 1-naphthyl. The aralkyl group has preferably 7 to 18 carbon atoms, and examples thereof include, for example, a benzyl or 3-phenylpropyl group. Each of these may be substituted by the above-mentioned substituent.

As X in formula (V) or (VI), preferable is a monovalent anion, for example, SbF₆, PF₆, and BF₄.

Next, the linking group L in formula (I) will be explained hereunder. L represents a linking group which links the light-absorptive portion D and the active portion A.

The linking group L is preferably a linking group containing at least one bond selected from the group consisting of methylene bond, ester bond, amide bond, sulfonamide bond, ether bond, and thioether bond, and may be a linking group having at least two of these bonds in combination. In this case, the light-absorptive portion D and the active portion A are preferably linked with a non-conjugated bond, and they are more preferably linked in such manner that the atomic group of the light-absorptive portion D is not bonded to the atomic group of the active portion A by way of a direct covalent bond (single bond) or conjugated bond, a partial construction of the active portion A is not a constructive part of the atomic group of the light-absorptive portion D, and the atomic group of the active portion A is linked with the linking group L to the atomic group of the light-absorptive portion D at a given distance by way of a non-conjugated bond.

Examples of the preferable linking group L include, for example, an ester bond represented by formula (a) or (b), an amide bond represented by any of formulae (c) to (f), a sulfonamide bond represented by formula (g), an ether bond, a thioether bond, and an amino bond.

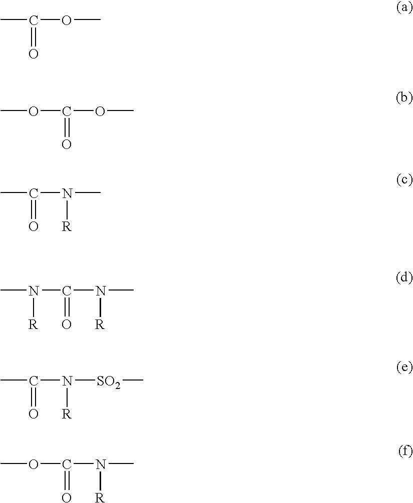

In formulae (c) to (f), R each independently represents a hydrogen atom, an alkyl group, or an aryl group.

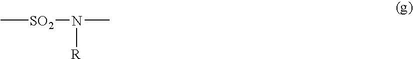

In formula (g), R represents a hydrogen atom, an alkyl group, or an aryl group.

Among the compounds represented by formula (I), especially preferable examples include those in which the light-absorptive portion D has a bis-cinnamylidenecycloalkanone structure, the active portion A is a group to give an S-triazine or 1-alkoxypyridinium containing a trichloromethyl group, and the linking group L is any one of the ester bond, amide bond, and sulfonamide bond.

Specific examples of the compound represented by formula (I) that can be preferably used in the present invention are shown below (Exampled compound S1 to Exampled compound S23), but the present invention is not limited to these compounds.

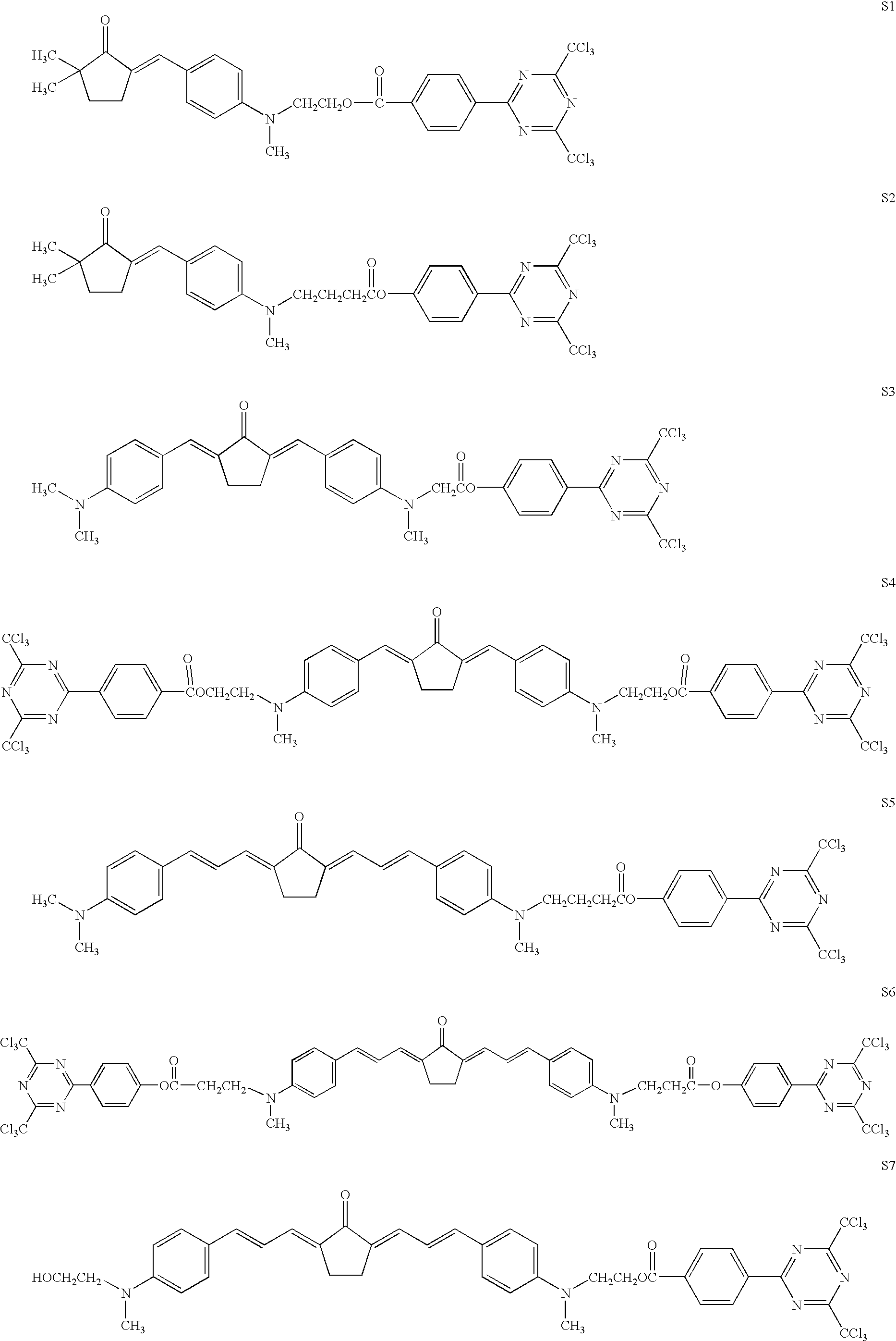

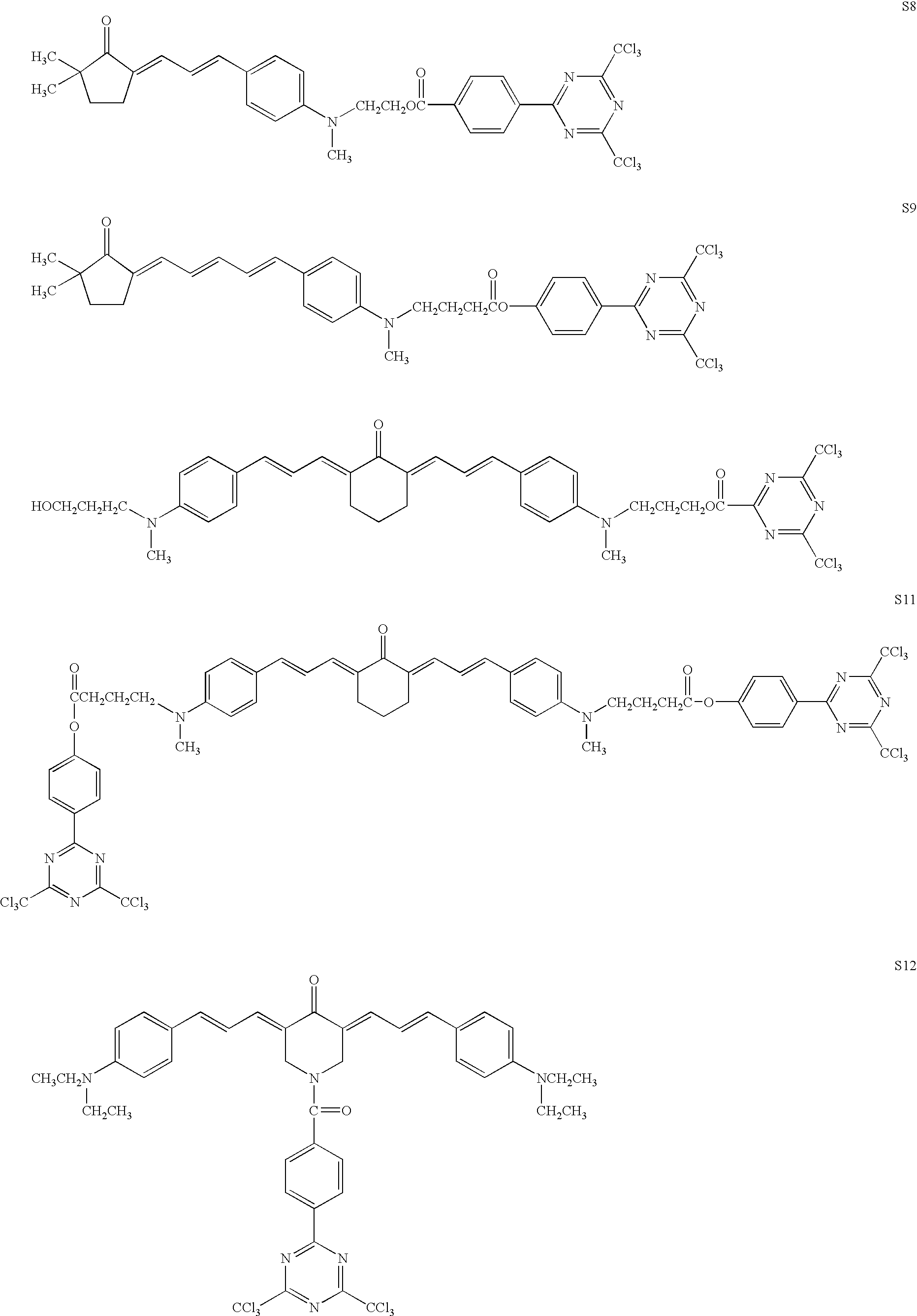

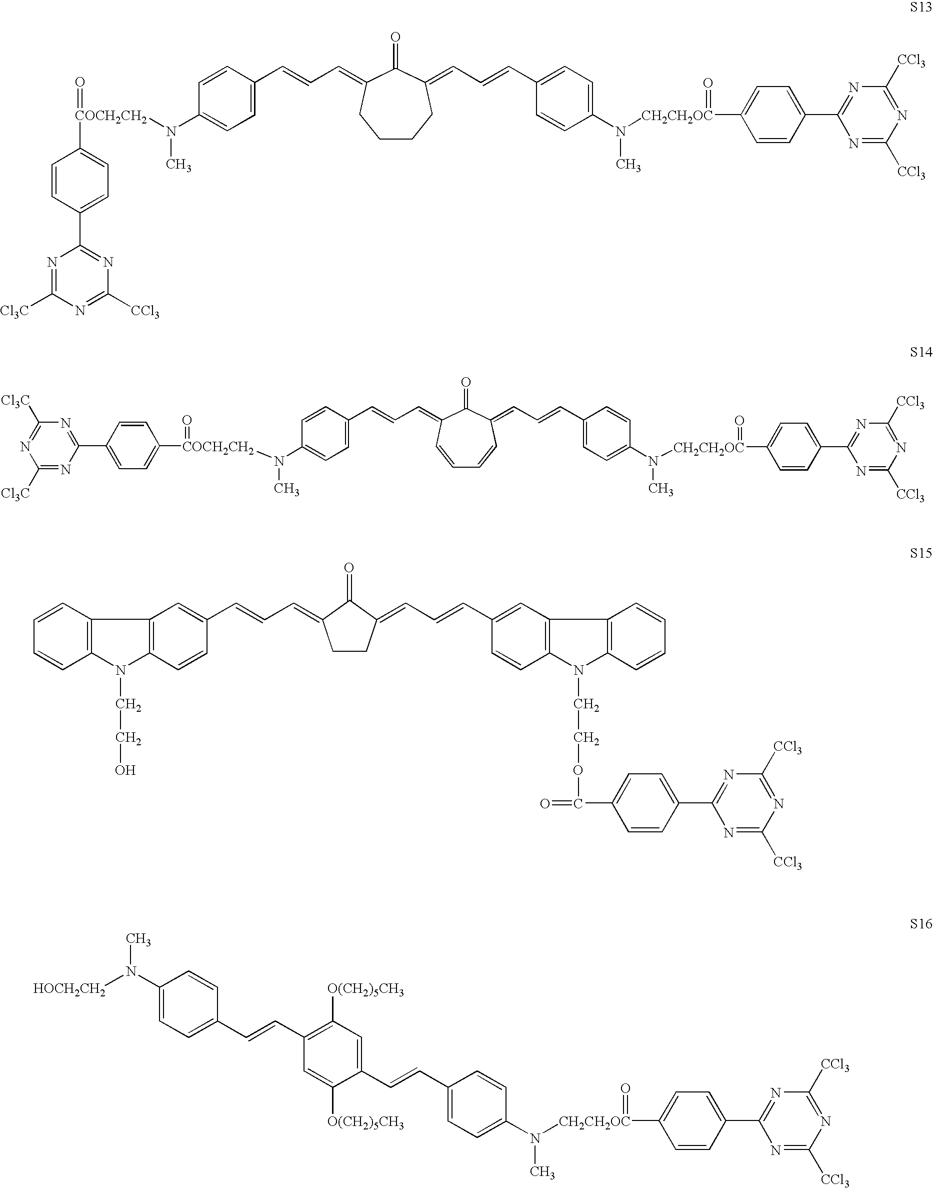

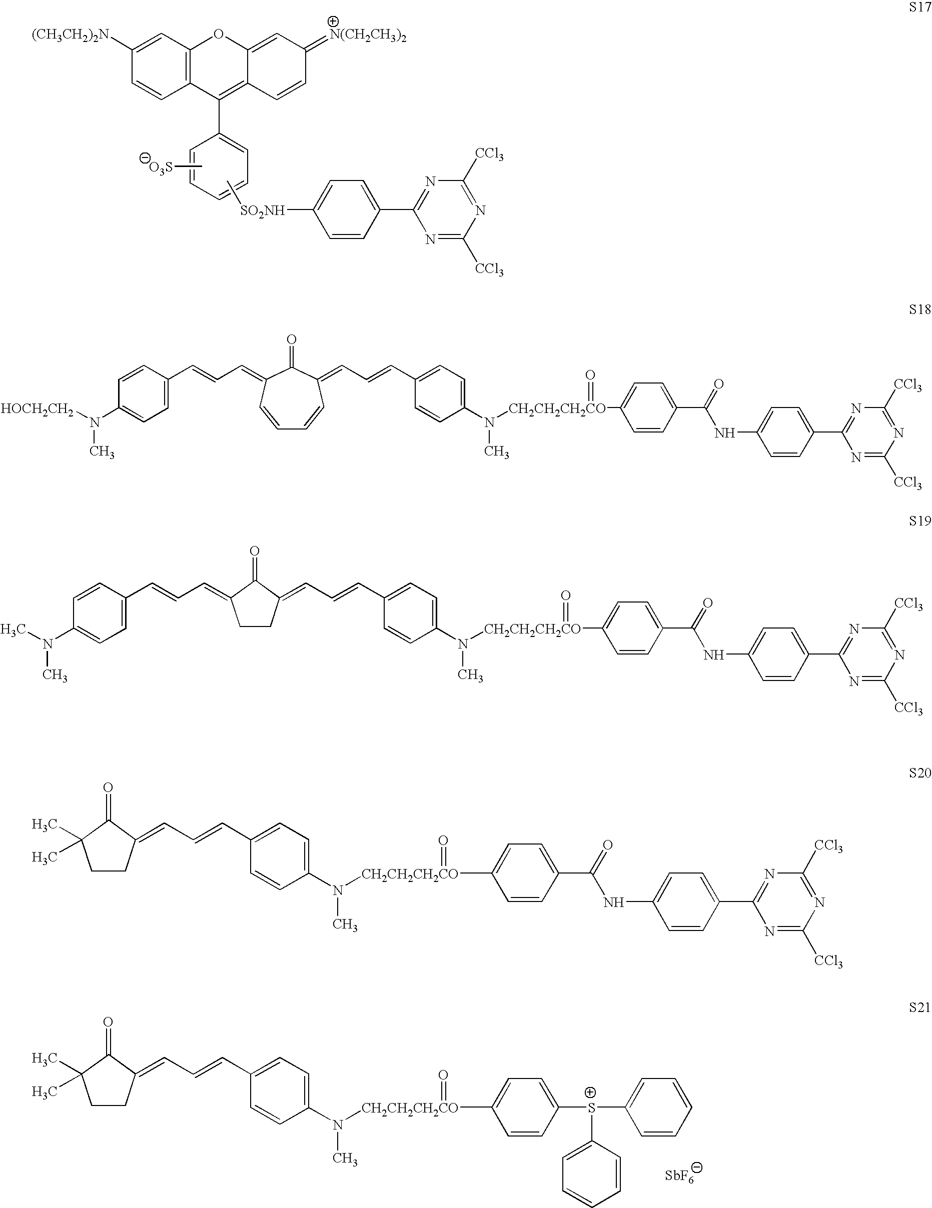

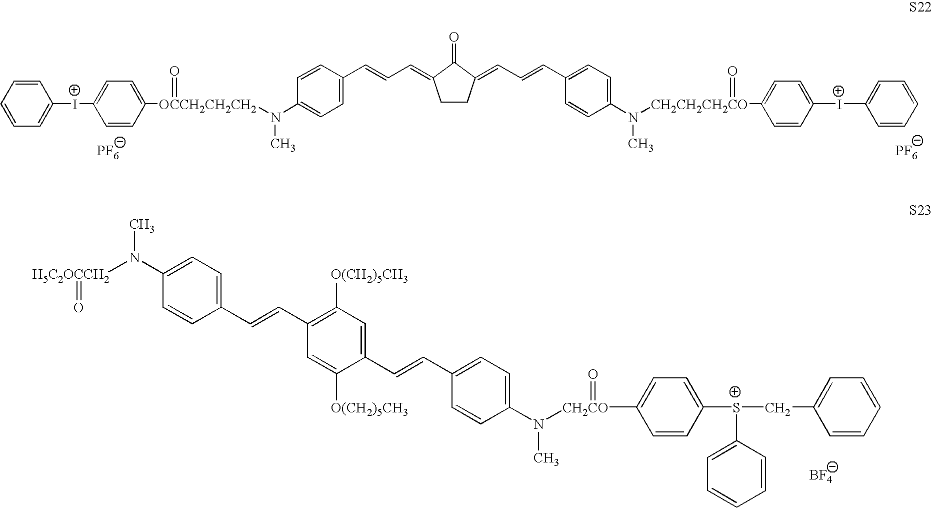

A method for obtaining the compound represented by formula (I) is not limited, but examples of the method include one in which a compound having the light-absorptive portion D containing a chemically reactive site is subjected to a chemical reaction with a compound having the active portion A having a chemically reactive site thereto, thereby to form the linking group L.

The content of the compound represented by formula (I) in the photosensitive composition of the present invention is preferably 0.01 to 10% by mass, more preferably 0.1 to 5% by mass, and particularly preferably 0.1 to 3% by mass, in the total of solid matters of the photosensitive composition. Furthermore, in view of the contents of other components, the content of the compound of formula (I) is preferably 0.01 to 10 parts by mass, and more preferably 0.1 to 5.0 parts by mass, to 100 parts by mass of the below-mentioned binder polymer (A).

In the photosensitive composition of the present invention, it is preferable that the photopolymerization initiator is small in the amount of any residual unreacted initiator and/or a decomposition product thereof. In case the photosensitive composition of the present invention is used for the two-photon absorption photorecording medium, the photopolymerization initiator is preferably decomposed and disposed after recording, from the viewpoint of the stability for the recorded signals.

In the photosensitive composition of the present invention, it is also possible to add any conventional polymerization initiator in combination with the photopolymerization initiator represented by formula (I), unless the effect of the present invention is not imparted.

### (A) Binder Polymer

Next, the binder polymer (A) will be explained hereinafter. As the binder polymers (A) in the present invention, use can be made of one selected from those can satisfy general properties required for two-photon absorption photorecording medium, which include those physical properties, for example, of transparency, film characteristics, and difference in refractive index between the polymer binder and the polymer from a photopolymerizable compound to be formed in the area exposed to a high-intensity light at the time of exposure

Specific examples of the binder polymer include polymethacrylic acid ester or a partial hydrolysate thereof; polyvinyl acetate or a hydrolysate thereof; polyvinyl alcohols or a partial acetal thereof; triacetylcellulose; polyisoprene; polybutadiene; polychloroprene; silicone rubber; polystyrene; polyvinylbutylal; polychloroprene; polyvinyl chloride; chlorinated polyethylene; chlorinated polypropylene; poly(N-vinylcarbazole) or a derivative thereof; poly(N-vinylpyrrolidone) or a derivative thereof; a copolymer of styrene and maleic anhydride, or a semiester thereof; and a copolymer containing as a polymerizable component at least one copolymerizable monomer selected from the group, for example, of acrylic acid, acrylic ester, methacrylic acid, methacrylic ester, acrylamide, acrylonitrile, ethylene, propylene, vinyl chloride, and vinyl acetate. Not only single compound of these but also a mixture of at least two of the compounds can be used.

Among these, preferable examples include polyisoprene, polybutadiene, polychloroprene, polyvinyl alcohol, polyvinyl acetal which is a partially acetallized product of polyvinyl alcohol, polyvinyl butylal, polyvinyl acetate, ethylene/vinyl acetate copolymer, vinyl chloride/vinyl acetate copolymer, or a mixture thereof.

In case photorecording is carried out by using a recording medium comprising the photosensitive composition for two-photon recording, it is general to carry out the steps of: subjecting a medium to exposure; transferring the polymerizable compound by heating, as a step for promoting the difference in refractive index caused by the exposure, or for stabilizing the recorded signals. In order that transferring of the polymerizable compound is efficiently performed by heating in the formed film, it is preferable that such matrix polymer preferably has a relatively low glass transition temperature prior to complete curing so that transferring of the monomer may be facilitated. From this viewpoint, specifically, it is preferable to use a polymer having a glass transition temperature of 180° C. or lower.

A preferable amount of the binder polymer to be added to the photosensitive composition is 10 to 99% by mass, and more preferably 30 to 80% by mass, in the total of solid matters.

### (B) Polymerizable Compound

As the polymerizable compound (B) for use in the photosensitive composition of the present invention, examples include a radical-polymerizable compound and a cation-polymerizable compound.

### i) Radical-Polymerizable Compound

As the (photo)radically polymerizable compound, examples include a compound having at least one addition-polymerizable ethylenically unsaturated double bond, for example, an unsaturated carboxylic acid and a salt thereof, an ester of an unsaturated carboxylic acid and an aliphatic polyhydric alcohol, and an amide of an unsaturated carboxylic acid and an aliphatic polyamine.

Specifically, examples include a monomer of an ester (monomeric ester) of an aliphatic polyhydric alcohol and an unsaturated carboxylic acid, and specific examples thereof are stated as follows:

As the acrylic acid ester, examples include ethyleneglycol diacrylate, triethyleneglycol diacrylate, 1,3-butanediol diacrylate, tetramethyleneglycol diacrylate, propyleneglycol diacrylate, neopentylglycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethyleneglycol diacrylate, pentaerythritol diacrylate, pentaerythritol triacrylate, pentaerythritol tetraacrylate, dipentaerythritol diacrylate, dipentaerythritol triacrylate, dipentaerythritol tetraacrylate, dipentaerythritol hexaacrylate, sorbitol triacrylate, sorbitol tetraacrylate, sorbitol pentaacrylate, sorbitol hexaacrylate, tri(acryloyloxyethyl)isocyanurate, polyester-acrylate oligomer, 2-phenoxyethyl acrylate, 2-phenoxyethyl methacrylate, phenolethoxylate monoacrylate, 2-(p-chlorophenoxy)ethyl acrylate, p-chlorophenyl acrylate, phenyl acrylate, 2-phenylethyl acrylate, (2-acryloxyethyl)ether of bisphenol A, ethoxylated bisphenol A diacrylate, 2-(1-naphthyloxy)ethyl acrylate, o-biphenyl methacrylate, o-biphenyl acrylate, etc.

As the methacrylic acid ester, examples include tetramethyleneglycol dimethacrylate, triethyleneglycol dimethacrylate, neopentylglycol dimethacrylate, trimethylolpropane trimethacrylate, trimethylolethane trimethacrylate, ethyleneglycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis-[p-(3-methacryloxy-2-hyroxypropoxy)phenyl]dimethylmethane, bis-[p(-acryloxyethoxy)phenyl]dimethylmethane, 2,2-bis-(4-methacryloyloxyphenyl)propane, 2-naphthyl methacrylate, etc.

### ii) Cation-Polymerizable Compound

As the (photo)cationically polymerizable compound, examples include cyclic ethers, as represented by an epoxy ring and an oxetane ring, thioethers, and vinyl ethers.

Specific examples of the compound include epoxy ring-containing compounds, such as polyalkyleneglycol diglycidyl ether, bisphenol A diglycidyl ether, glycerol triglycidyl ether, diglycerol triglycidyl ether, diglycidyl hexahydrophthalate, trimethylolpropane diglycidyl ether, allyl glycidyl ether, phenyl glycidyl ether, and cyclohexene oxide; and oxetane ring-containing compounds, such as 3-ethyl-3-[(2-ethylhexyloxy)methyl]oxetane, and bis{[1-ethyl(3 -oxetanyl)]methyl}ether, etc.

Further, in the present invention, it is preferable to use a photopolymerizable compound low in refractive index, for enlarging the difference in refractive index from the binder polymer (A). In particular, examples of the preferable monomer having a refractive index of 1.49 or less include aliphatic monomers, such as polyethyleneglycol monoacrylate, polyethyleneglycol diacrylate, polyethyleneglycol diacrylate, polyethyleneglycol dimethacrylate, trimethylolpropane triacrylate, trimethylolpropane trimethacrylate, hexanediol diacrylate, pentaerythritol tetraacrylate, etc.; and fluorine-containing monomers, such as 1H,1H,2H,2H-heptadecafluorodecyl methacrylate (for example, trade name: Viscoat 17FM, manufactured by Osaka Organic Chemical Industry), 1H,1H,5H-octafluoropentyl methacrylate (trade name: Viscoat 8FM, manufactured by Osaka Organic Chemical Industry), 2-(perfluoro-3-methylbutyl)ethyl methacrylate (trade name: M-3420, manufactured by Daikin Industries, Ltd.), 2-(perfluorodecyl)ethyl methacrylate (trade name: M-2020, manufactured by Daikin Industries, Ltd.), 3-(1H,1H,9H-hexadecafluorononyloxy)-1,2-epoxyproane (trade name: E-5844, manufactured by Daikin Industries, Ltd.), 1,4-bis(2′,3′-epoxypropyl)-perfluoro-n-butane (trade name: E-7432, manufactured by Daikin Industries, Ltd.), etc.

Use can also be made of an oligomer-type or polymer-type of any of the compounds exemplified in the above.

The polymerizable compound (B) is preferably contained within the range of 1 to 80% by mass, and more preferably within the range of 10 to 60% by mass, in the total solid content of the photosensitive composition of the present invention. In relation to the other components, the polymerizable compound is contained preferably in an amount of 10 to 1,000 parts by mass, and more preferably in an amount of 10 to 100 parts by mass, per 100 parts by mass of the jointly used binder polymer (A).

### (D) Solvent

The photosensitive composition containing the components (A) to (C) is dissolved in a favorable solvent, followed by application to a subject. Examples of the solvent favorable for the photosensitive composition of the present invention include acetone, methyl ethyl ketone, methyl isobutyl ketone, cyclohexanone, benzene, toluene, xylene, chlorobenzene, tetrahydrofuran, methylcellosolve, ethylcellosolve, methylcellosolve acetate, ethylcellosolve acetate, ethyl acetate, 1,4-dioxane, 1,2-dichloroethane, dichloromethane, chloroform, methanol, ethanol, and isopropanol. A mixed solvent of these can also be used.

In view of uniform application, the solid content in case of preparing a coating liquid of the photosensitive composition is preferably about 10 to 50% by mass.

### [Two-Photon Absorption Photorecording Medium]

Next, the two-photon absorption photorecording medium (optical recording medium) of the present invention will be explained hereinafter. One feature of the two-photon absorption photorecording medium of the present invention resides in having a photosensitive layer containing the photosensitive composition.

### (Support)

As the support for use in the two-photon absorption photorecording medium of the present invention, a substrate film can be used which possesses transparency. Specific examples include resinous films, such as polyethylene film, polypropylene film, poly(fluorinated ethylene) film, poly(fluorinated vinylidene) film, polyvinyl chloride film, polyvinylidene chloride film, ethylene/vinyl alcohol copolymer film, polyvinyl alcohol film, poly(methyl methacrylate) film; polyethersulfone film, polyetheretherketone film, polyamide film, tetrafluoroethylene/perfluoroalkyl vinyl ether copolymer film, polyester film (e.g. polyethylene terephthalate film), and polyimide film.

The film thickness of the support is properly selected according to the intended purpose, but is generally within the range of 2 to 200 μm, preferably 10 to 50 μm.

The two-photon absorption photorecording medium of the present invention has the support provided thereon with the photosensitive layer containing the photosensitive composition, and the photosensitive layer is generally formed by applying the photosensitive composition onto the support.

A coating liquid of the photosensitive layer is prepared by dissolving the photosensitive composition in a proper solvent as described above, and the resultant coating liquid is applied onto the support substrate by the aid of a spin coater, a gravure coater, a comma coater, a bar coater, etc., followed by drying the coating liquid, thereby the two-photon absorption photorecording medium of the present invention, preferably a two-photon absorption photorecording medium for recording volume hologram, is obtained.

The thickness of the photosensitive composition for recording use (e.g. the thickness of a photosensitive layer) is preferably to be thicker to record an image to a certain volume in a high density and in a large capacity as possible as they can be. Even in such case, it is preferable that the optical density (OD) in a wavelength of recording light and read-in light is low, as a high optical density of the photosensitive layer disturbs a large change in refractive index of the materials.

From these viewpoints, the thickness of the photosensitive layer is within the range of preferably 50 to 2,000 μm, more preferably 500 to 1,000 μm, and the most preferably 200 to 500 μm. With a view to hardening the photosensitive layer uniformly to a deep place by polymerization, the optical density (OD) of the photosensitive layer in this thickness is preferably 0.4 or below, more preferably 0.3 or below, and the most preferably 0.2 or below.

In case the photosensitive composition for recording after drying possesses adhesiveness, it may be protected by laminating on the surface thereof with a protective film. For example, a thin layer film of thickness about 0.1 to 5 μm, which is composed of a material as exemplified for the substrate film of the support, can be used as the protective film for laminating. In this case, the contact surface between the recording material layer and the laminate film may be subjected to a mold-releasing treatment for facilitating delamination.

The recording medium of the present invention thus obtained is utilized in photorecording, by carrying out the recording step through exposure to light. In order to cause a two-photon absorption reaction, the use of a pulse laser is preferable. The peak-power of the laser is preferably 1 kW to 100 GW, and a pulse width is preferably 1 femto second to 1 nano seconds

As a light source for recording, use can be preferably made of argon laser, krypton laser, YAG laser, titanium-sapphire laser, and fiber laser, etc., and the vibration wavelength is preferably 400 to 1,600 nm.

The recording mechanism according to the two-photon absorption photorecording medium of the present invention is considered to be the same as in that in the conventional technique.

In case the photosensitive composition formed in filmy state (namely, the photosensitive layer on the recording medium) is exposed to light, photopolymerization is initiated in a portion where light is high in its intensity, to permit formation of a concentration gradient of the photopolymerizable compound so that diffusive transfer of the photopolymerizable compound takes place from a portion where light intensity is low to a portion where light intensity is high. As the result, a region where the photopolymerizable compound is existent in dense state and a region where the binder polymer is existent as a main component are formed, according to the intensity of the recording light, thereby to form a difference in refractive index between those regions.

With respect to the difference in refractive index An between the exposed region and the non-exposed region, it is no matter whichever is larger in refractive index, but the difference is preferably at least 0.01 or more.

Recording in the photosensitive layer according to the two-photon absorption photorecording medium of the present invention is thus carried out.

As the photosensitive composition of the present invention is excellent in recording sensitivity even in case of the amount of the photopolymerization initiator to be added being small, the two-photon absorption photorecording medium of the present invention enables recording at a high sensitivity. In addition, with respect to the recording medium after recording, any residual components of the photopolymerization initiator remaining in the photosensitive layer and any decomposition product thereof are small so that the recorded recording medium is excellent in transparency, thus affording large difference in refractive index and excellent recording quality.

Furthermore, the recording medium of the present invention can suppress the amount of the photopolymerization initiator to be added while achieving excellent characteristics, so that it is advantageous in the aspect of cost, and also has an advantageous feature that the photopolymerization initiator scarcely gives bad influence even in case of contacting with the skin in the course of handling.

According to the photosensitive composition of the present invention and the two-photon absorption photorecording medium using the same, it is possible to cause two-photon absorption by using a relatively low output laser, and is also possible to utilize energy in high excited state generated as the result of the two-photon absorption as initiation energy for chemical reaction such as polymerization.

The photosensitive composition of the present invention can cause two-photon absorption by using a relative low power laser, and can efficiently transfer the energy from the highly excited state due to the two-photon absorption, to generate radicals, thereby attaining a sufficient recording sensitivity even in case the content of a photopolymerization initiator is small. Further, since the photosensitive composition of the present invention is excited even if it is irradiated with a light of wavelength longer by double than the maximum absorption wavelength due to two-photon absorption, polymerization is initiated not from the surface part irradiated with the light but from the vicinity of focus where photon density is high, thus permitting the initiation of polymerization from the three-dimensionally arbitrary region.

Further, the two-photon absorption photorecording medium of the present invention acquires sufficient recording sensitivity, and the resultant photosensitive layer is suppressed from the influence on physical properties due to an unreacted photopolymerization initiator or a decomposition residue thereof, thus maintaining high optical transparency. Thus, it is possible to obtain a recorded layer of great deviation in refractive index.

The present invention will be described in more detail based on the following examples, but the invention is not intended to be limited thereto.

### EXAMPLES

### Example 1

The components of the following composition were blended, to prepare a photosensitive composition for recording use:

| | |
|---|---|
| Poly(methyl methacrylate) (trade name: Elvacite | 100 parts by mass |
| 2041, produced by DuPont) | |
| Polyethyleneglycol dimethacrylate | 60 parts by mass |
| (trade name: 9G, produced by Shin-Nakamura | |
| Chemical Co., Ltd.) | |
| Photopolymerization initiator (Exemplified | 0.23 parts by mass |
| compound S7) | |
| Toluene | 30 parts by mass |
| Methyl ethyl ketone (MEK) | 30 parts by mass |
| Tetrahydrofuran (THF) | 40 parts by mass |

Using a bar coater, the above photosensitive composition solution was applied onto a polyethylene terephthalate (PET) film (trade name: Lumilar T-60; produced by Toray) of thickness 38 μm, so that a dried film would be formed in a dried film thickness of 200 μm, thereby to produce a photosensitive medium for recording use. An optical concentration of this photosensitive layer at 630 nm was 0.09.

From the support (PET film) side, the photosensitive medium was irradiated with 840-nm titanium-sapphire laser beam (peak-power 7 kW, pulse width 100 fs) for recording.

The record was then fixed, by heating of and UV-initiated polymerization in the recorded medium. Further, from the result of spectral evaluation, Δn=0.046 was obtained. Herein, the “Δn” has the same meaning as defined in the above, and means the difference in refractive index (n) between the exposed region and the non-exposed region on the sample.

### Comparative Example 1

A photosensitive composition was prepared in the same manner as in Example 1, except that, as the photopolymerization initiator, the following photopolymerization initiator system (0.15 parts by mass of Sensitizer dye R1 and 0.11 part by mass of Photopolymerization initiator R2 not having the structure of formula (I) were combined and separately added to the system) was used in place of Exemplified compound S7, and photorecording was carried out in the same manner as in Example 1.

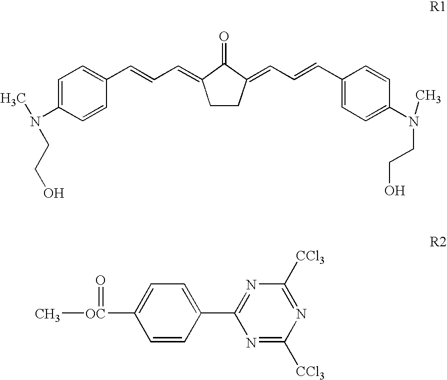

As a result, it is found that the polymerization scarcely proceeded, and that from the results of calculation from the spectral evaluation results, it was Δn=0.011, thus showing conspicuously poor recording performance, as compared with Example 1.

### Example 2

A photosensitive composition was prepared in the same manner as in Example 1, except that 0.38 parts by mass of Exampled compound S10 was used, as the photopolymerization initiator, in place of Exampled compound S7.

Using a bar coater, a solution of the thus-obtained photosensitive composition was applied onto a polyethylene terephthalate (PET) film (trade name: Lumilar-T-60; produced by Toray) of thickness 38 μm, so that a dried film would be formed having a dried film thickness of 200 μm, thereby to produce a photosensitive medium for recording use. An optical concentration of this photosensitive layer at 630 nm was 0.08.

From the PET side, the photosensitive medium was irradiated with 840-nm titanium-sapphire laser beam (peak-power 7 kW, pulse width 100 fs) for recording.

The record was then fixed, by heating of and UV-initiated polymerization in the recorded medium. Further, from the calculated results from spectral evaluation, Δn=0.035 was obtained.

### Comparative Example 2

A photosensitive composition was prepared in the same manner as in Example 2, except that, as the photopolymerization initiator, the following photopolymerization initiator system (0.17 parts by mass of Sensitizer dye R3 and 0.22 part by mass of Photopolymerization initiator R2 not having the structure of formula (I) were combined and separately added to the system) was used in place of Exemplified compound S10, and photorecording was carried out in the same manner as in Example 2.

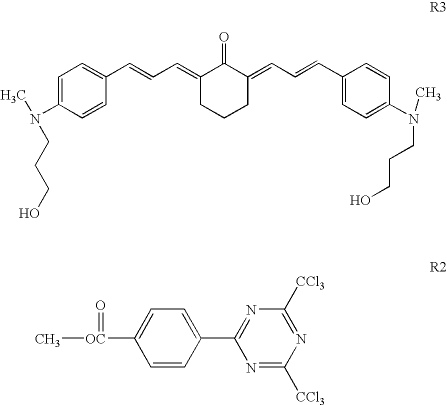

As a result, it was observed that the polymerization scarcely proceeded, and that from the results of calculation from the spectral evaluation results, it was Δn=0.006, thus showing conspicuously poor recording performance, as compared with Example 2.

As is apparent from the comparison of the result of Examples 1 and 2 with those of Comparative examples 1 and 2, it is evident that the polymerization scarcely took place in Comparative examples 1 and 2 in which a compound having the active portion A and a compound having the light-absorptive portion D were used in combination, thus showing poor recording performance. Contrary to this, the polymerization took pace and a sufficient recording sensitivity was attained in Examples 1 and 2 in each of which use was made of the specific photopolymerization initiator having the active portion A and the light-absorptive portion D linked by the linking group L in such mode that these portions were arranged in the vicinity by covalent bond.

From this fact, it is understood that since the specific photopolymerization initiator that can be used in the present invention has a structure in which the active portion A and the light-absorptive portion D are arranged in a near position each other via a covalent bond, transfer of photoelectron can take place efficiently and energy can be efficiently transferred from the highly excited state by two-photon absorption, thus exhibiting quite high radical generating efficiency and attaining sufficient recording sensitivity even at a low concentration, as compared with the case where the active portion A and the light-absorptive portion D are not linked.

Furthermore, the two-photon absorption photorecording medium obtained by using the photosensitive composition requires only a small content of the photopolymerization initiator, thus resulting in reduction of residual product like unreacted initiator and/or decomposition material and enabling suppression of bad influence of these undesired remaining products on the film physical properties and optical characteristics of the resultant recorded film to the minimum.

Having described our invention as related to the present embodiments, it is our intention that the invention not be limited by any of the details of the description, unless otherwise specified, but rather be construed broadly within its spirit and scope as set out in the accompanying claims.

This non-provisional application claims priority under 35 U.S.C. §119(a) on Patent Application No. 2007-040067, filed in Japan on Feb. 20, 2007, which is entirely herein incorporated by reference.

What we claim is:

1. A photosensitive composition, comprising a binder polymer, a polymerizable compound, and a compound of formula (I):
D-L-A Formula (I)
wherein D represents a light-absorptive portion composed of a group to give a two-photon absorption compound which has at least 100 GM of two-photon absorption cross-section in a wavelength longer than 400 nm; A represents an active portion capable of interacting with the light-absorptive portion D that is excited by light, to generate free radicals; and L represents a linking group which links the light-absorptive portion D with the active portion A.

2. The photosensitive composition according to claim 1, wherein the compound represented by formula (I) is contained in an amount of 0.1 to 3.0% by mass.

3. The photosensitive composition according to claim 1, wherein the linking group L in formula (I) represents a linking group linking at least one linkage selected from the group consisting of a methylene bond, an ester bond, an amide bond, a sulfonamide bond, an ether bond, and a thioether bond, and the light-absorptive portion D and active portion A are linked by a non-conjugated bond.

4. The photosensitive composition according to claim 1, wherein the light-absorptive portion D is a group derived from a compound represented by formula (II) or (III): 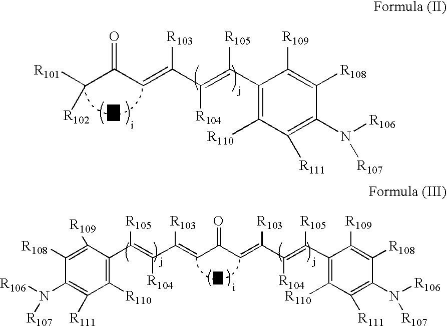
wherein Y represents a halogen atom, an alkyl group having 1 to 18 carbon atoms, an alkoxy group having 1 to 18 carbon atoms, or a methine or methylene group which may be substituted by an aryl group having 6 to 18 carbon atoms; i represents an integer of 1 to 4; R₁₀₁ and R₁₀₂ each independently represent a hydrogen atom, an alkyl group having 1 to 18 carbon atoms or an aryl group having 6 to 18 carbon atoms; R₁₀₃, R₁₀₄ and R₁₀₅ each independently represent a hydrogen atom, a halogen atom, an alkyl group having 1 to 18 carbon atoms, or an aryl group having 6 to 18 carbon atoms; j represents an integer of 0 to 3; R₁₀₆ and R₁₀₇ each independently represent an alkyl group having 1 to 18 carbon atoms or an aryl group having 6 to 18 carbon atoms; R₁₀₈, R₁₀₉, R₁₁₀ and R₁₁₁ each independently represent a hydrogen atom, a halogen atom, a cyano group, an alkyl group having 1 to 18 carbon atoms, an alkoxy group having 1 to 18 carbon atoms, an acyl group having 1 to 18 carbon atoms, an acylamino group having 1 to 18 carbon atom, a carbamoyl group having 1 to 18 carbon atom, a sulfonamido group having 1 to 18 carbon atoms, a sulfamoyl group having 1 to 18 carbon atoms, an amino group, an alkylamino group having 1 to 18 carbon atoms, an arylamino group having 6 to 18 carbon atoms, or a hydroxyl group, in which any two of these groups may be bonded together, to form a ring; and any one of R₁₀₁ to R₁₁₁ has a functional group necessary for reacting with a compound containing the active portion A, to form the linking group L.

5. The photosensitive composition according to claim 1, wherein the active portion A is a group derived from a compound represented by formula (IV): 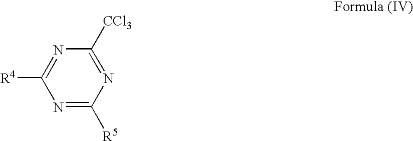
wherein R⁴ and R⁵ each independently represent a hydrogen atom, an alkyl group, a substituted alkyl group, an aryl group, a substituted aryl group, an alkenyl group, or a substituted alkenyl group, in which one of R⁴ and R⁵ has at least one functional group necessary for reacting with a compound containing the light-absorptive potion D, thereby to form the linking group L.

6. A two-photon absorption photorecording medium having a photosensitive layer containing the photosensitive composition according to claim 1.
